(19) United States
(12) Patent Application Publication
(10) Pub. No.: US 2014/0097397 A1
(43) Pub. Date: Apr. 10, 2014

(54) RESISTIVE MEMORY DEVICE AND MEMORY APPARATUS AND DATA PROCESSING SYSTEM HAVING THE SAME

(71) Applicant: SK HYNIX INC., Icheon (KR)

(72) Inventors: Woo Young PARK, Icheon (KR); Kee Jeung LEE, Icheon (KR); Beom Yong KIM, Icheon (KR)

(73) Assignee: SK HYNIX INC., Icheon (KR)

(21) Appl. No.: 13/842,919

(22) Filed: Mar. 15, 2013

(30) Foreign Application Priority Data
Oct. 8, 2012 (KR) 10-2012-0111184

(51) Int. Cl. H01L 45/00

(52) U.S. Cl. CPC H01L 45/145
USPC 257/4; 257/5

(57) ABSTRACT

A resistive memory device includes a first electrode layer, a second electrode layer, and a first variable resistive layer and a second variable resistive layer stacked at least once between the first electrode layer and the second electrode layer. The first variable resistive material layer may include a metal nitride layer having a resistivity higher than that of the first electrode layer or the second electrode layer and less than or equal to that of an insulating material.

### CROSS-REFERENCES TO RELATED APPLICATION

This application claims priority under 35 U.S.C. 119(a) to Korean application number 10-2012-0111184, filed on Oct. 8, 2012, in the Korean Patent Office, which is incorporated by reference in its entirety.

### BACKGROUND OF THE INVENTION

1. Technical Field

The present invention relates to a semiconductor integrated device, and more particularly, to a resistive memory device and a memory apparatus, and a data processing system including the same.

2. Related Art

Flash memory devices which are representative of non-volatile memory devices have become increasingly more highly integrated. Recently, there is a need for a high integration technology below 20 nm. Since flash memory devices operate at a low voltage for low power consumption, flash memory devices encounter physical and electrical limitations due to an insufficient current margin. Thus, studies on non-volatile memory devices that can replace such flash memory devices have been actively developed.

Resistive memory devices are memory devices that use a current transfer characteristic of resistive material, which varies according to an applied voltage. Resistive memory devices have received attention as nonvolatile memory devices which can replace the flash memory devices, and typically include phase-change RAMs (PRAMs), resistive RAMs (ReRAMs), and the like.

In general, PRAMs are fabricated in a metal-insulator-metal (MIM) structure using a transition metal oxide (TMO). Further, resistive memory devices that have been developed recently perform a switching operation using filaments formed in the resistive material layer, and can be easily adapted to scaled-down memory devices.

FIG. 1 is a view illustrating a structure of a general resistive memory device.

As shown in FIG. 1, a resistive memory device 10 has a structure in which a first electrode layer 11, a variable resistive material layer 13, and a second electrode layer 15 are stacked.

The first and second electrode layer 11 and 15 may be formed, for example, of titanium nitride (TiN), and the variable resistive material layer 13 may be formed, for example, of metal oxide, such as titanium oxide TiₓO_{y} such as TiO₂ or TiO₂₋ₓ (where x is integer).

FIG. 2 is a view illustrating a unit cell of a general resistive memory apparatus.

As shown in FIG. 2, a memory cell is connected between a bit line BL and a word line WL and the memory cell may include a resistive memory device R and a selection device S. The resistive memory device R may include the structure illustrated in FIG. 1 and the selection device S may include a diode, a transistor, or the like.

FIG. 3 is a graph illustrating a current/voltage characteristic of the resistive memory device illustrated in FIG. 1.

Referring to FIG. 3, the current/voltage characteristic can be seen when a voltage is applied from a negative voltage of −2V to a positive voltage of +2V. The resistive memory device illustrated in FIG. 1 exhibits a resistive switching behavior such that it has a set state at the applied voltage of +2V and a reset state at the applied voltage of −2V. However, it can be seen that an operation current is as high as ±250 μA.

FIG. 4 is a view illustrating another general resistive memory device.

A resistive memory device 10-1, as illustrated in FIG. 4, may have a structure in which a first electrode layer 11, a first variable resistive material layer 13-1, a second variable resistive material layer 13-2, and a second electrode layer 15 are stacked.

The first and second electrode layers 11 and 15 may be formed, for example, of titanium nitride (TiN). The first variable resistive material layer 13-1 may be formed of a TaₓO_{y}-based material, for example, Ta₂O₅ (where x and y are integers) and a second variable resistive material layer 13-2 may be formed of TiₓO_{y}-based material, for example, TiO₂, TiO₂₋ₓ or the like (where x is integer).

In the resistive memory device 10-1 illustrated in FIG. 4, the variable resistive layer has a dual structure, which is different from the resistive memory device 10 illustrated in FIG. 1.

FIG. 5 is a graph illustrating a current/voltage characteristic of the resistive memory device illustrated in FIG. 4.

Since the resistive memory device 10-1 illustrated in FIG. 4 uses a transition metal layer having a dual structure, endurance and data retention characteristics can be improved. However, as shown in FIG. 5, the operation voltage range is as high as −3V to +3V and the operation current is as high as ±50 μA.

The transition metal oxide used in the resistive memory device preferably has good endurance, long lifespan, and good on/off and retention characteristics to ensure reliability of the device. However, typical transition metal oxide results in high power consumption due to high driving voltage and current.

Sneak current, which flows in a path other than a selected device, occurs due to the high operation voltage and current. Thus, a method of controlling the sneak current is necessary.

Therefore, there is a need for a resistive memory device which has a non-linear current characteristic and a low current/voltage characteristic in a low resistive memory state.

### SUMMARY

According to one aspect of an exemplary embodiment, there is provided a resistive memory device. The resistive memory device may include: a first electrode layer; a second electrode layer; and a first variable resistive layer and a second variable resistive layer repeatedly stacked at least once between the first electrode layer and the second electrode layer. The first variable resistive material layer may include a metal nitride layer having a resistivity higher than that of the first electrode layer or the second electrode layer and less than or equal to that of an insulating material.

According to another aspect of an exemplary embodiment, there is provided a resistive memory apparatus. The resistive memory apparatus may include: a memory cell array including a plurality of memory cells connected between bit lines and word lines; and a controller configured to control data read and write for a selected memory cell in the memory cell array. Each of the plurality of memory cells may include a resistive memory device. The resistive memory device may include a first electrode layer and a second electrode layer; and a first variable resistive layer and a second variable resistive layer repeatedly stacked at least once between the first electrode layer and the second electrode layer. The first variable resistive material layer may include a metal nitride layer having a resistivity higher than the first electrode layer or the second electrode layer and having resistivity less than or equal to that of an insulating material.

According to another aspect of an exemplary embodiment, there is provided a data processing system. The data processing system may include: a resistive memory apparatus; and a memory controller configured to access the resistive memory apparatus in response to request of a host. The resistive memory apparatus may include: a memory cell array including a plurality of memory cells connected between bit lines and word lines, each of the plurality of memory cells including a resistive memory device; and a controller configured to control an operation of the memory cell array. The resistive memory device may include a first electrode layer and a second electrode layer; and a first variable resistive layer and a second variable resistive layer repeatedly stacked at least once between the first electrode layer and the second electrode layer. The first variable resistive material layer may include a metal nitride layer having a resistivity higher than the first electrode layer or the second electrode layer and less than or equal to that of an insulating material.

According to another aspect of an exemplary embodiment, there is provided a data processing system. The data processing system may include: a processor configured to control an overall operation; an operation memory configured to store an application, data, and a control signal required for an operation of the processor; a resistive memory apparatus configured to be accessed by the processor; and a user interface configured to perform data input/output (I/O) between the processor and a user. The resistive memory apparatus may include: a memory cell array including a plurality of memory cells connected between bit lines and word lines, each of the plurality of memory cells including a resistive memory device; and a controller configured to control an operation of the memory cell array. The resistive memory device may include a first electrode layer and a second electrode layer; and a first variable resistive layer and a second variable resistive layer repeatedly stacked at least once between the first electrode layer and the second electrode layer. The first variable resistive material layer may include a metal nitride layer having a resistivity higher than the first electrode layer or the second electrode layer and less than or equal to that of an insulating material.

These and other features, aspects, and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 illustrates a general resistive memory device;

FIG. 2 is a view illustrating a structure of a general resistive memory apparatus;

FIG. 3 is a graph illustrating a current/voltage characteristic of the resistive memory device of FIG. 1;

FIG. 4 illustrates another general resistive memory device;

FIG. 5 is a graph illustrating a current/voltage characteristic of the resistive memory device of FIG. 4;

FIG. 6 is a view illustrating a structure of a resistive memory device according to an exemplary embodiment of the present invention;

FIG. 7 is a view illustrating a resistivity of an electrode layer and a second variable resistive material layer included in the resistive memory device of FIG. 6;

FIGS. 8 to 16 are views illustrating structures of resistive memory devices according to various exemplary embodiments of the present invention;

FIG. 17 is a graph illustrating a current/voltage characteristic of a resistive memory device according to an exemplary embodiment of the present invention;

FIGS. 18 and 19 are views illustrating structures of resistive memory cell arrays according to exemplary embodiments of the present invention;

FIG. 20 is a view illustrating a configuration of a memory apparatus according to exemplary embodiments of the present invention;

FIG. 21 is a view illustrating a configuration of a data processing system according to an embodiment of the present invention; and

FIG. 22 is a view illustrating a configuration of a data processing system according to another exemplary embodiment of the present invention.

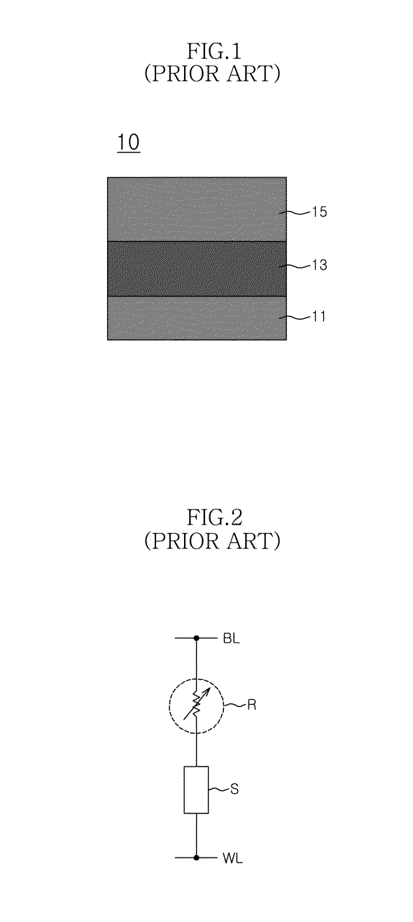

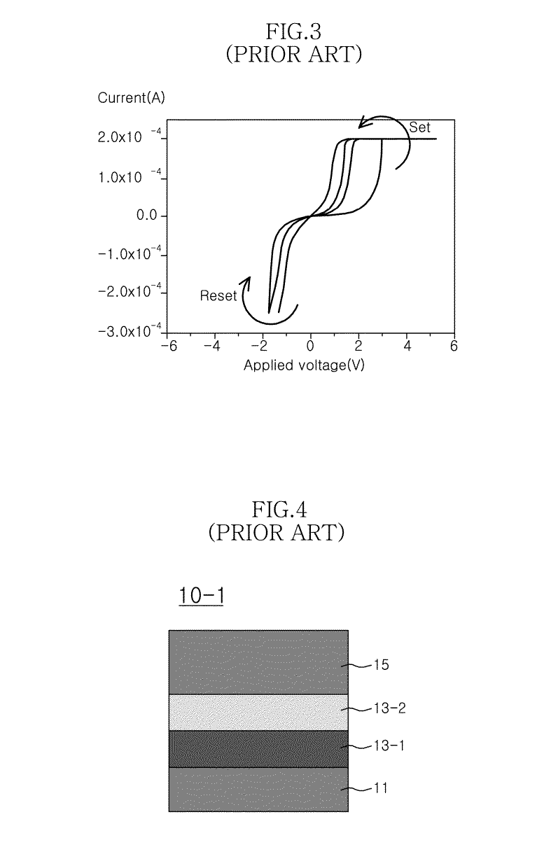

### DETAILED DESCRIPTION

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

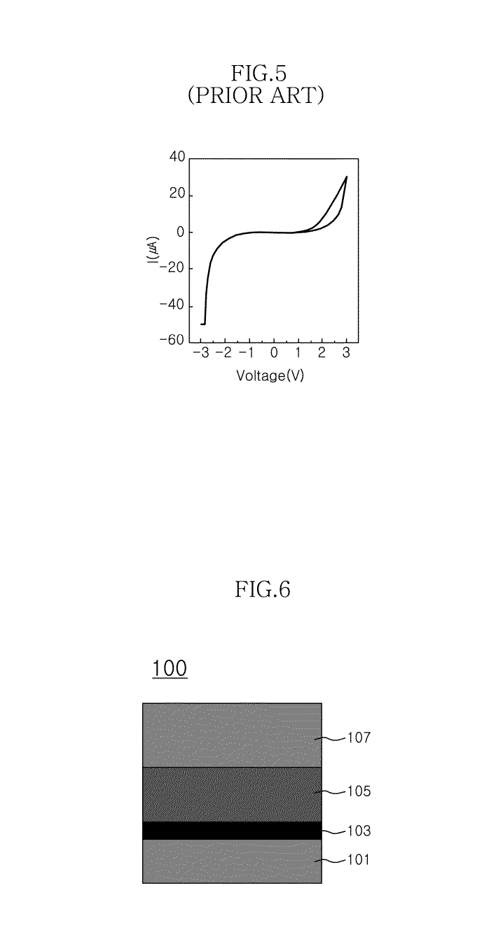

FIG. 6 is a view illustrating a structure of a resistive memory device according to an exemplary embodiment of the present invention.

Referring to FIG. 6, a resistive memory device 100 according to an exemplary embodiment may include a structure in which a first variable resistive material layer 103 and a second variable resistive material layer 105 are stacked at least once between a first electrode layer 101 and a second electrode layer 107.

FIG. 6 illustrates the structure in which the first variable resistive material layer 103 is formed on the first electrode layer 101, but the present invention is not limited to this structure. The resistive memory device may have a structure in which the first variable resistive material layer 103 is formed between the second variable resistive material layer 105 and the second electrode layer 107.

Each of the first electrode layer 101 and the second electrode layer 107 may be formed of (i) a metal material such as titanium (Ti), tantalum (Ta), tungsten (W), copper (Cu), ruthenium (Ru), platinum (Pt), nickel (Ni), iridium (Ir), aluminum (Al), zirconium (Zr), hafnium (Hf), silver (Ag), and gold (Au), (ii) a nitride layer including the metal material, (iii) a silicide layer of the metal material, or (iv) an oxide layer including the metal material.

The second variable resistive material layer 105 may be formed of (i) metal oxide such as zirconium oxide (ZrOx), nickel oxide (NiOx), hafnium oxide (HfOx), titanium oxide (TiOx), tantalum oxide (TaOx), aluminum oxide (AlOx), lanthanum oxide (LaOx), niobium oxide (NbOx), and strontium titanium oxide (SrTiOx), magnesium oxide (MgOx), a combination material thereof, (ii) Perovskite such as PrCnMnO, LaCaMnO, and Sr(Zr)TiO₃, or (iii) a solid-state electrolyte such as germanium silicon (GeS), germanium selenium (GeSe), copper sulfide (Cu₂S), and silver germanium selenium (AgGeSe) (where x is integer). However, the material for the first variable resistive material layer 105 is not limited thereto.

Alternatively, the first variable resistive material layer 103 may include a metal nitride layer. Specifically, the first variable resistive material layer 103 may have a resistivity higher than that of the first electrode layer 101 and less than or equal to that of an insulating material. Wherein the first variable resistive material layer 103 includes a metal nitride layer, and wherein resistivity of the metal nitride in a reset state is (i) higher than a resistivity of the first electrode layer or the second electrode layer and (ii) less than or equal to resistivity of the second variable resistive material layer in a reset state. For example, the first variable resistive material layer 103 may have a resistivity higher than 150μΩ and less than or equal to that of the insulating material.

In an embodiment of the present invention, the first variable resistive material layer 103 may be formed of a material such as titanium nitride (TiN), titanium carbon nitride (TiCN), titanium aluminum nitride (TiAIN), titanium silicon nitride (TiSiN), tantalum nitride (TaN), tantalum carbon nitride (TaCN), tantalum silicon nitride (TaSiN), tantalum titanium nitride (TaTiN), titanium silicon nitride (TiSiN), hafnium nitride (HfN), zirconium nitride (ZrN), tungsten nitride (WN), aluminum nitride (AlN), and a combination thereof. However, the material for the first variable resistive material layer 103 is not limited thereto. Further, when the first variable resistive material layer 103 is formed of a metal nitride layer, the metal nitride layer can be formed through nitration using a gas such as nitrogen gas (N₂), hydrogen gas (H₂), ammonia gas (NH₃), argon gas (Ar), and a combination thereof.

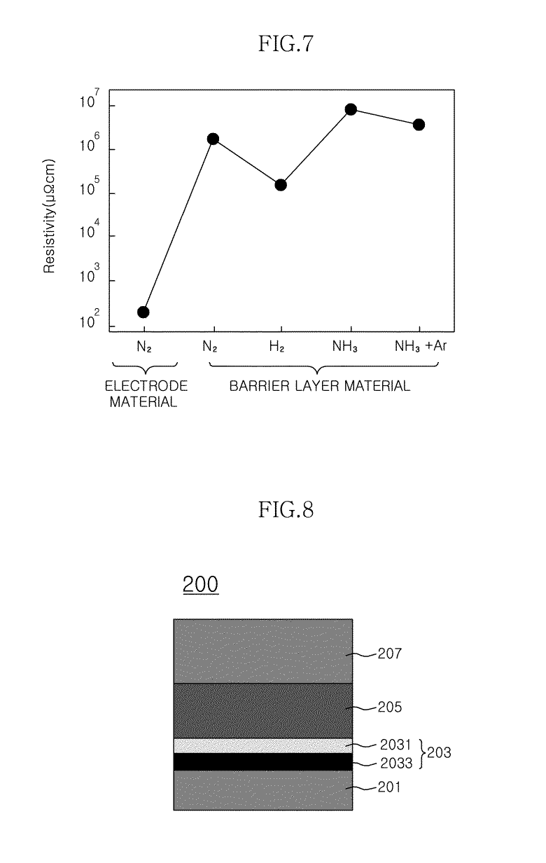

FIG. 7 illustrates a resistivity of an electrode layer and a first variable resistive material layer of the resistive memory device illustrated in FIG. 6.

More specifically, FIG. 7 illustrates a difference in resistivity between the first variable resistive material layer 103 and the first electrode layer 101 when the layers are formed under the conditions indicated in Table 1.

Table 1 shows resistivity according to a deposition condition of the first variable resistive material layer 103 formed of TaₓN_{y} (where x is integer).

TABLE 1

| | | Resistivity (μΩ) | Resistivity (μΩ) |
|---|---|---|---|
| | | at 20° C. (when | at 20° C. (when |
| | Plasma | deposition was | deposition was |
| Material | gas | made at 300° C.) | made at 350° C.) |
| TiN | N₂ | 182 | 75 |
| TaₓN_{y} | N₂ | Resistivity of insulator | 1741850 |
| TaₓN_{y} | H₂ | 124375 | 192727 |
| TaₓN_{y} | NH₃ | Resistivity of insulator | 8205135 |
| TaₓN_{y} | NH₃ + Ar | Resistivity of insulator | 7867887 |

It can be seen from FIG. 7 and Table 1 that tantalum nitride can have the resistivity in a range of 10⁵ to 10⁷μΩ, which is substantially the same resistivity as that of an insulator, when a deposition temperature and a kind of plasma gas are properly adjusted. The resistivity of the tantalum nitride layer is 10³ to 10⁶ times higher than that of titanium nitride, which is an electrode layer.

In an embodiment, the first variable resistive material layer 103 may be formed using a plasma-enhanced atomic layer deposition (PEALD) method. It can be seen that when the deposition temperature is controlled to 300° C., a first variable resistive material layer 103 having an insulating property can be obtained.

In a resistive memory device including only transition metal oxide between the electrode layers, there is a limitation in that it is difficult to reduce an operation voltage and operation current due to high resistance of the transition metal oxide and low power driving. However, the resistive memory device according to an embodiment of the present invention includes at least one first variable resistive material layer 103 between the electrode layer and the transition metal oxide.

The first variable resistive material layer 103 is selected from materials having a resistivity higher than the electrode layer and less than or equal to that of an insulating material. The metal nitride, which may be used as the first variable resistive material layer 103, may be used as a data storage material since metal nitride has a switching characteristic, even though the switching characteristic is lower than that of a metal oxide. Further, since metal nitride has a resistivity that is less than or equal to the resistivity of an insulating material, the resistive memory device can operate at a low voltage and current to ensure low power characteristics. As a result, when the resistive memory device has the stacked structure of the transition metal oxide and the metal nitride, endurance and retention characteristics can be improved and a low operation voltage/operation current can be ensured.

Conventionally, a voltage of about ½ of an operation voltage is applied to a periphery of a selected cell when a memory apparatus operates. However, in an exemplary embodiment, the low-power drivable variable resistive material layer can further minimize the sneak current, which may be applied to the periphery of the selected memory cell, and can therefore provide a memory apparatus having stable random access operation characteristic.

Therefore, in a resistive memory device according to an exemplary embodiment of the present invention, disadvantages that may result from a combination of a metal oxide and metal nitride can be offset by the advantage of a low power characteristic. Thus, high endurance and data retention characteristics can be ensured.

Further, in this sense, the first variable resistive material layer 103 may be referred to as an auxiliary variable resistive material layer.

FIGS. 8 to 16 illustrate structures of resistive memory devices according to exemplary embodiments of the present invention.

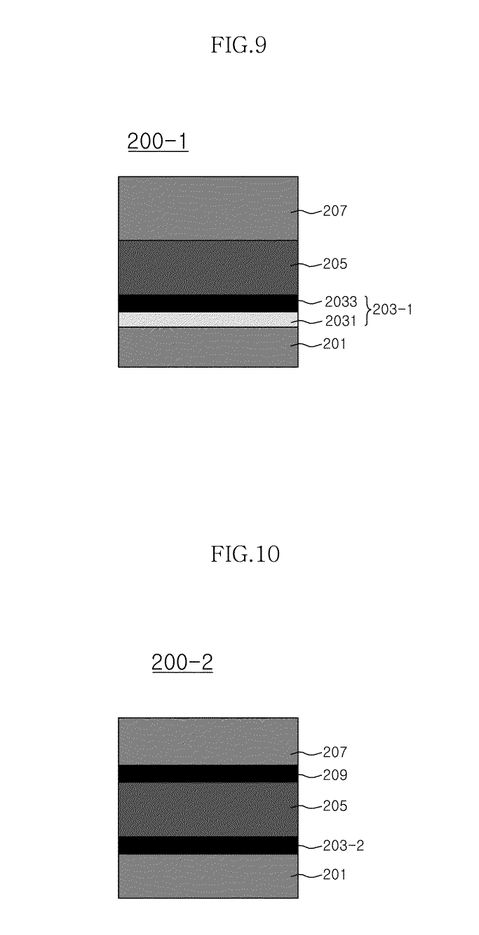

First, FIGS. 8 and 9 show examples in which a first variable resistive material layer 203 is formed of a dual structure of a metal oxide layer and a metal nitride layer. The structures thereof will be described in further detail.

Referring to FIG. 8, a resistive memory device 200 according to an exemplary embodiment has a stacked structure including a first electrode layer 201, a first variable resistive material layer 203, a second variable resistive material layer 205, and a second electrode layer 207. Specifically, the first variable resistive material layer 203 has a dual structure. For example, in an embodiment, as shown in FIG. 8, the first variable resistive material layer 203 includes a first variable resistive layer 2033 formed of metal nitride and a second variable resistive layer 2031 formed of metal oxide provided on the first variable resistive layer 2033.

However, a stacking order of the first variable resistive layer 2033 and the second variable resistive layer 2031 is not limited thereto. As shown in FIG. 9, a first variable resistive material layer 203-1 may be formed by sequentially stacking a second variable resistive layer 2031 formed of metal oxide and then a first variable resistive layer 2033 formed of metal nitride on the first electrode layer 201.

The metal nitride employed as the first variable resistive layer 2033 is selected from materials having a resistivity higher than that of the first electrode layer 201 and less than or equal to that of an insulating material. Further, the metal oxide employed as the second variable resistive layer 2031 may be formed of the same material as the second variable resistive material layer 205, a material that is the same as the second variable resistive material layer 205 but having a different composition ratio from that of the second variable resistive material layer 205, or a material that is different from the second variable resistive material layer 205.

FIG. 10 is a view illustrating a structure of a resistive memory device 200-2 according to another exemplary embodiment of the present invention.

Referring to FIG. 10, the resistive memory device 200-2 has a stacked structure including a first electrode layer 201, a first variable resistive material layer 203-2, a second variable resistive material layer 205, a third variable resistive material layer 209, and a second electrode layer 207. That is, in this embodiment, the resistive memory device 200-2 includes the first variable resistive material layer 203-2 and third variable resistive material layer 209, which enable low power driving of the device, in addition to the second variable resistive material layer 205 having a good switching characteristic. In this sense, the first and the third variable resistive material layers 203-2 and 209 may each be referred to as an auxiliary variable resistive material layer.

Here, each of the first variable resistive material layer 203-2 and the third variable resistive material layer 209 may be formed using metal nitride. Each of the first variable resistive material layer 203-2 and the third variable resistive material layer 209 may be selected from materials having a resistivity higher than those of the first electrode layer 201 and the second electrode layer 207, and less than or equal to that of an insulating material. For example, the first variable resistive material layer 203-2 and the third variable resistive material layer 209 includes a metal nitride layer, and wherein resistivity of the metal nitride in a reset state is (i) higher than a resistivity of the first electrode layer or the second electrode layer and (ii) less than or equal to resistivity of the second variable resistive material layer in a reset state.

In the resistive memory device 200-2 illustrated in FIG. 10, the additional auxiliary variable resistive material layer 203-2 is formed at an interface between the first electrode layer 201 and the second variable resistive material layer 205, and the additional auxiliary variable resistive material layer 209 is formed at an interface between the second electrode layer 207 and the second variable resistive material layer 205. Therefore, the problems that may result from a high operation voltage/current for driving the second variable resistive material layer 205 that has high resistivity can be effectively solved by providing low-power drivable auxiliary variable resistive material layers 203-2 and 209.

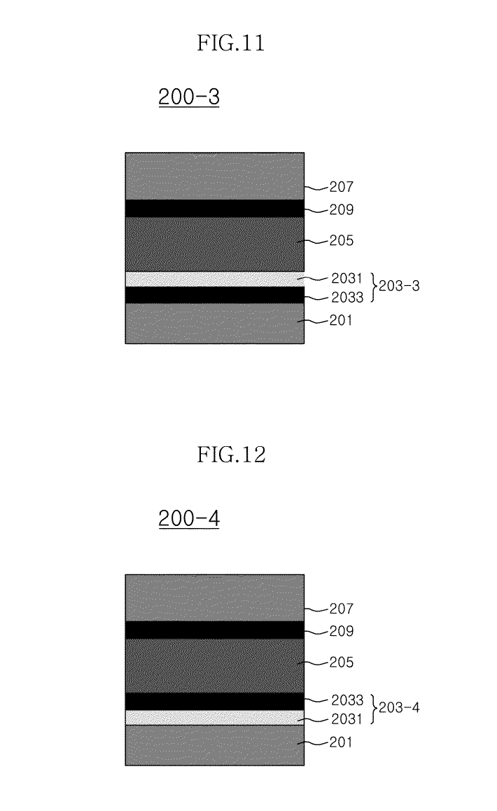

Resistive memory devices illustrated in FIGS. 11 and 12 can be regarded as variants of the resistive memory device 200-2 illustrated in FIG. 10.

That is, a resistive memory device 200-3 of FIG. 11 includes a first variable resistive material layer 203-3 having a dual structure of a metal nitride layer and a metal oxide layer. A resistive memory device 200-4 of FIG. 12 includes a first variable resistive material layer 203-4 having a dual structure of a metal oxide layer and a metal nitride layer.

More specifically, the resistive memory device 200-3 of FIG. 11 may include the first variable resistive material layer 203-3 formed on a first electrode layer 201, a second variable resistive material layer 205 formed on the first variable resistive material layer 203-3, a third variable resistive material layer 209 formed on the second variable resistive material layer 205, and a second electrode layer 207 formed on the third variable resistive material layer 209.

The first variable resistive material layer 203-3 may include a first variable resistive layer 2033 and a second variable resistive layer 2031. The first variable resistive layer 2033 and the second variable resistive layer 2031 may include a metal nitride layer and a metal oxide layer, respectively. The third variable resistive material layer 209 may include a metal nitride layer.

In the resistive memory device 200-4 of FIG. 12, the first variable resistive material layer 203-4 may have a stacked structure of the second variable resistive layer 2031 and the first variable resistive layer 2033. The second variable resistive layer 2031 may be formed of metal oxide and the first variable resistive layer 2033 may be formed of metal nitride.

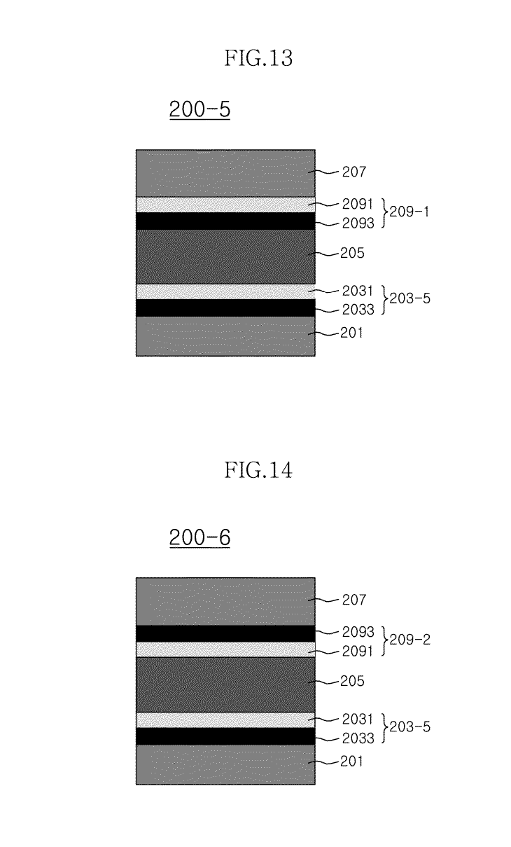

FIGS. 13 and 14 each show a resistive memory device according to another embodiment of the present invention. Resistive memory device illustrated in FIGS. 13 and 14 may be regarded as variants of the resistive memory device 200-3 illustrated in FIG. 11.

That is, in a resistive memory devices 200-5 illustrated in FIG. 13, a first variable resistive material layer 203-5 may have a structure in which a first variable resistive layer 2033 and a second variable resistive layer 2031 are sequentially stacked, and a third variable resistive material layer 209-1 may have a structure in which a third variable resistive layer 2093 and a fourth variable resistive layer 2091 are sequentially stacked.

In an embodiment, each of the first variable resistive layer 2033 and the third variable resistive layer 2093 may be formed of metal nitride, and each of the second variable resistive layer 2031 and the fourth variable resistive layer 2091 may be formed of metal oxide.

A resistive memory device 200-6 illustrated in FIG. 14 has a similar structure to the resistive memory device 200-5 illustrated in FIG. 13. However, in the resistive memory device 200-6 of FIG. 14, the third variable resistive material layer 209-2 may have a structure in which the fourth variable resistive layer 2091 and the third variable resistive layer 2093 are sequentially stacked on the second variable resistive material layer 205.

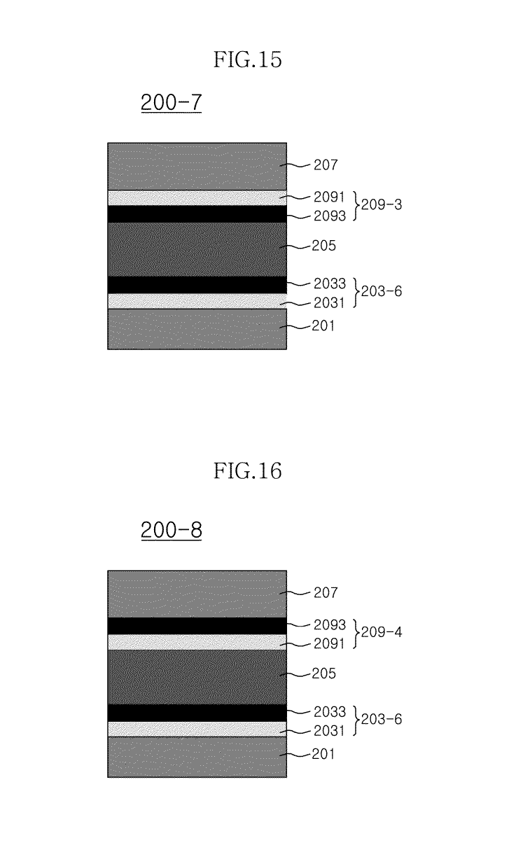

Resistive memory devices illustrated in FIGS. 15 and 16 may be variants of the resistive memory device 200-3 illustrated in FIG. 12.

Referring to FIG. 15, a resistive memory device 200-7 according to the exemplary embodiment may have a stacked structure of a first electrode layer 201, a first variable resistive material layer 203-6, a second variable resistive material layer 205, a third variable resistive material layer 209-3, and a second electrode layer 207. The first variable resistive material layer 203-6 may have a structure in which the second variable resistive layer 2031 and the first variable resistive layer 2033 are sequentially stacked, and a third variable resistive material layer 209-3 may have a structure in which the third variable resistive layer 2093 and the fourth variable resistive layer 2091 are sequentially stacked.

A resistive memory device 200-8 illustrated in FIG. 16 has a similar structure to the resistive memory device 200-7 illustrated in FIG. 15. However, the third variable resistive material layer 209-4 may have a structure in which the fourth variable resistive layer 2091 and the third variable resistive layer 2093 are sequentially stacked on the second variable resistive material layer 205.

Referring to FIGS. 15 and 16, each of the first variable resistive layer 2033 and the third variable resistive layer 2093 may be formed of metal nitride, and each of the second variable resistive layer 2031 and the fourth variable resistive layer 2091 may be formed of metal oxide.

Structures of resistive memory devices according to exemplary embodiments of the present invention have been described with reference to FIGS. 8 to 16.

In the above-described exemplary embodiments, the metal nitride employed as the auxiliary variable resistive material layer has a resistivity higher than the electrode layers and less than or equal to that of an insulating material.

Further, the metal oxide employed as the auxiliary variable resistive material layer may be formed of the same material as the variable resistive material layer, a material that is the same as the variable resistive material layer but different in a composition ratio from that of the variable resistive material layer, or a material that is different from the variable resistive material layer.

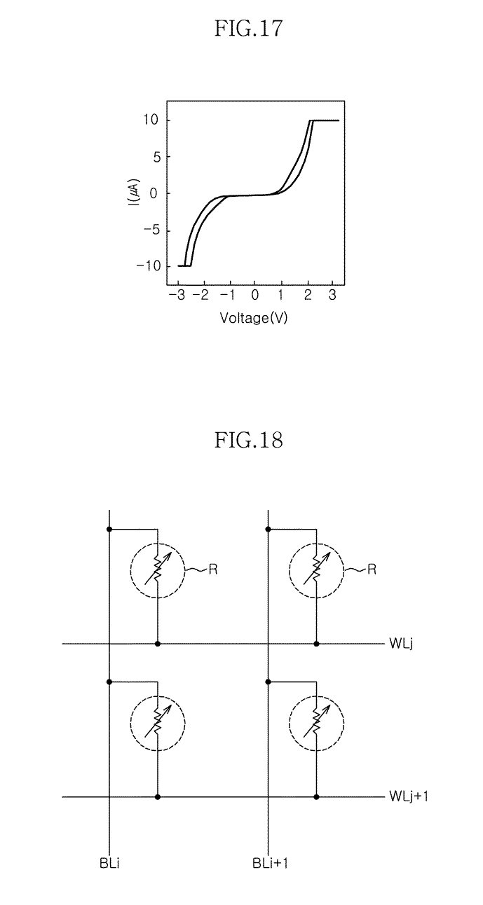

FIG. 17 is a graph illustrating a current/voltage characteristic of a resistive memory device according to an exemplary embodiment of the present invention.

In a resistive memory device according to an exemplary embodiment of the present invention, specifically, in the resistive memory device 100 illustrated in FIG. 6, the first variable resistive material layer 103 may be formed of metal nitride. The first variable resistive material layer 103 has a resistivity higher than that of the first electrode layer 101 and less than or equal to that of an insulating material, and is provided at the interface between the first electrode layer 101 and the second variable resistive material layer 105.

As shown in FIG. 17, the resistive memory device 100 can operate even at an operation voltage between −2.7 V and +2.7 V and an operation current of ±10 μA as shown in FIG. 17.

As compared with FIG. 5 described above, it can be seen that the operation voltage representing a resistive switching behavior is lowered and the operation current is also significantly reduced from ±50 μA to ±10 μA.

In addition to the low power characteristic, the endurance and retention characteristics of the variable resistive material layer (transition metal oxide layer) are also guaranteed so that lifespan, operation reliability, and low power characteristic of a semiconductor memory apparatus can be ensured.

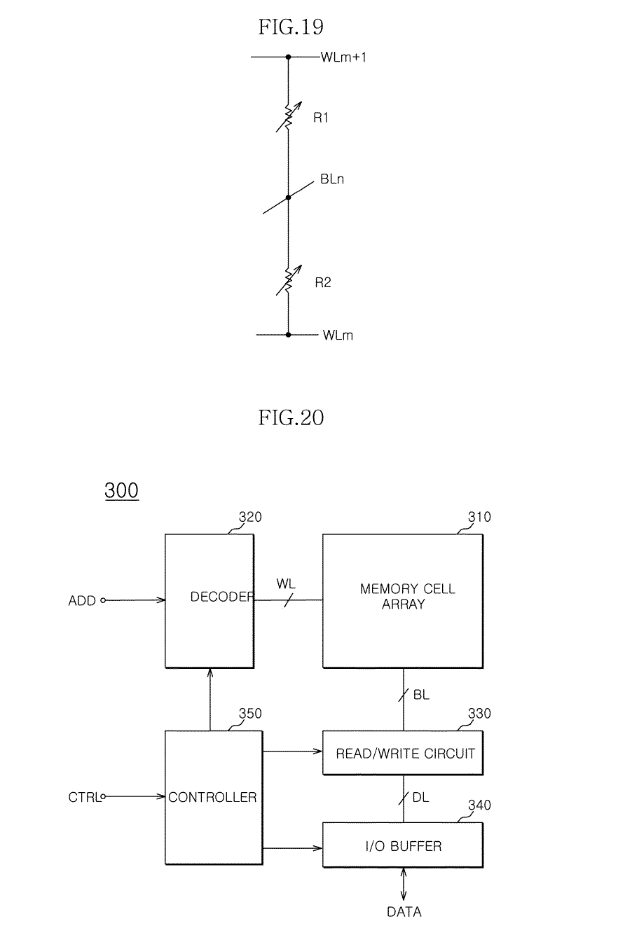

FIGS. 18 and 19 are views illustrating configurations of resistive memory cell arrays according to exemplary embodiments of the present invention.

First, FIG. 18 illustrates a configuration of a memory cell array including memory cells formed between a plurality of bit lines BLi and BLi+1 and a plurality of word lines WLj and WLj+1 (where I and j are integers).

As illustrated in FIG. 18, a memory cell array may be configured by forming resistive memory devices R between the bit lines BLi and BLi+1 and the word lines WLj and WLj+1.

FIG. 18 illustrates a memory cell array having a structure in which a selection device is not used. However, a selection device such as a transistor or a diode may be added between the resistive memory devices R and the word lines.

FIG. 19 illustrates a memory cell array configured in a crossbar array type.

In the crossbar type memory cell array, resistive memory devices R1 and R2, each of which is a unit memory cell, may be formed to have a symmetrical structure based on a bit line BLn (where n is integer). That is, resistive memory devices R1 and R2 may be fabricated to have a structure in which an upper electrode of the resistive memory device R2 formed in a lower side and a lower electrode of the resistive memory device R1 formed in an upper side are integrated into a single electrode which is commonly shared and used by the resistive memory devices R1 and R2.

The cross bar type memory cell array is not limited to the symmetrical structure and may be formed by repeatedly stacking resistive memory devices having the same structure.

The reference numerals WLm and WLm+1 (where m is integer) denote word lines.

FIG. 19 illustrates that the unit memory cells are configured with the resistive memory devices R1 and R2, but the unit memory cell according to an embodiment of the present invention is not limited to this configuration. The unit memory cell may be configured such that the resistive memory devices R1 and R2 and a selection device are coupled in series.

In the memory cell arrays illustrated in FIGS. 18 and 19, any one among the resistive memory devices illustrated in FIGS. 6 and 8 to 16 may be employed as the resistive memory device. That is, any resistive memory devices illustrated in FIGS. 6 and 8 to 16 can be placed between a pair of electrode layers. Any of these variable resistive material layers may include, for example, a metal nitride layer having a resistivity higher than that of the electrode layers and less than or equal to that of an insulating material.

As explained above, in a conventional memory device including only a variable resistive material layer between the electrode layers, the variable resistive material has high resistance. Thus, there is a limitation in reducing operation voltage of the memory device. However, the resistive memory device according to an exemplary embodiment of the present invention includes an auxiliary variable resistive material layer having low voltage/low current operation characteristic and a switching characteristic so that the voltage applied to the resistive memory cell can be reduced to ensure low power characteristics. Thus, sneak current can be controlled and a memory apparatus having a stable random access operation characteristic can be provided.

FIG. 20 is a view illustrating a configuration of a memory apparatus according to an exemplary embodiment of the present invention.

Referring to FIG. 20, a memory apparatus 300 according to an exemplary embodiment of the present invention includes a memory cell array 310, a decoder 320, a read/write circuit 330, an input/output (I/O) buffer 340, and a controller 350.

Each of a plurality of memory cells constituting the memory cell array 310 may be configured to include any one of the resistive memory devices illustrated in FIGS. 6 and 8 to 16. Further, the plurality of memory cells in the memory cell array 310 is coupled to the decoder 320 through a word line WL and to the read/write circuit 330 through a bit line BL.

The decoder 320 receives an external address ADD and decodes a row address and a column address to be accessed to the memory cell array 310. The decoder 320 is controlled by the controller 350 which operates according to a control signal CTRL.

The read/write circuit 330 receives data DATA from the I/O buffer 340, and writes data in a selected memory cell of the memory cell array 310 under control of the controller 350 or reads out data from a selected memory cell of the memory cell array 310 to the I/O buffer 340 under control of the controller 350.

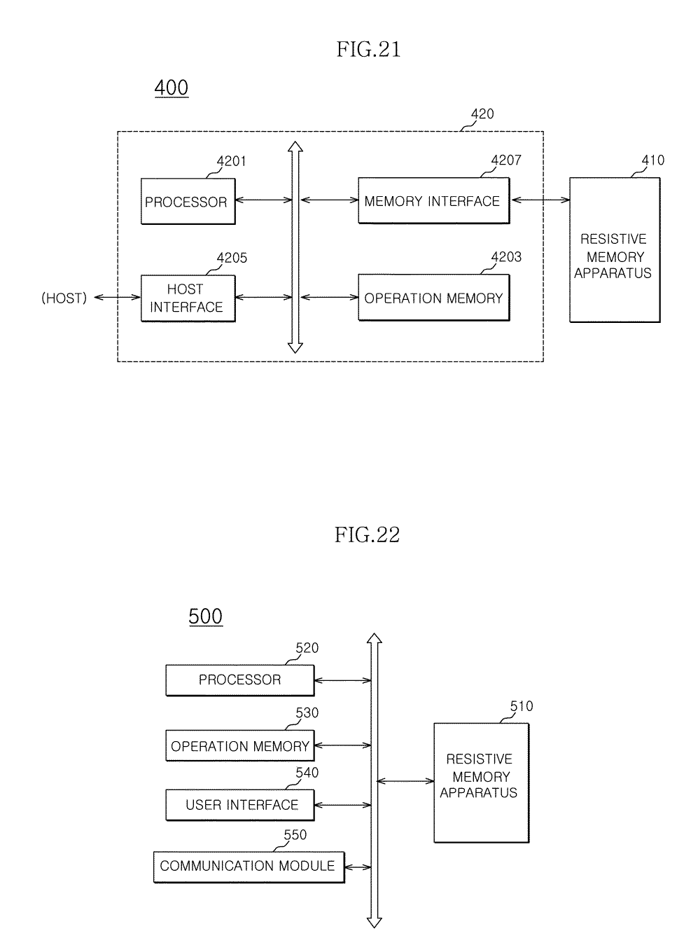

FIG. 21 is a view illustrating a configuration of a data processing system according to an exemplary embodiment of the present invention.

A data processing system 400 illustrated in FIG. 21 may include a memory controller 420 coupled to and disposed between a host and a resistive memory apparatus 410.

The memory controller 420 may be configured to access the resistive memory apparatus 410 in response to request of the host. Thus the memory controller 420 may include a processor 4201, an operation memory 4203, a host interface 4205, and a memory interface 4207.

The processor 4201 may control an overall operation of the memory controller 420, and the operation memory 4203 may store an application, data, a control signal, and the like required for operation of the memory controller 420.

The host interface 4205 performs protocol conversion for exchange of data/control signal between the host and the memory controller 420. The memory interface 4207 performs protocol conversion for exchange of data/control signal between the memory controller 420 and the resistive memory apparatus 410.

The resistive memory apparatus 410 may include a memory cell array using a resistive memory device, in which a variable resistive material is formed between two electrode layers, as a unit memory cell. In another embodiment, the resistive memory apparatus 410 may include a unit memory cell in which a resistive memory device and a selection device are coupled in series. Specifically, the resistive memory device may be any of the resistive memory devices illustrated in FIGS. 6 and 8 to 16.

In an exemplary embodiment of the present invention, the data processing system illustrated in FIG. 21 may be a memory card, but the data processing system is not limited thereto.

FIG. 22 is a view illustrating a configuration of a data processing system according to another exemplary embodiment of the present invention.

A data processing system 500 illustrated in FIG. 22 includes a resistive memory apparatus 510, a processor 520, an operation memory 530, and a user interface 540. If necessary, the data processing system 500 may further include a communication module 550.

The processor 520 may be a central processing unit (CPU), and the operation memory 530 may store an application program, data, a control signal, and the like required for an operation of the data processing system 500. The user interface 540 provides an environment accessible to the data processing system 500 by a user and provides a data processing procedure, result, and the like of the data processing system 500 to the user.

For example, the resistive memory apparatus 510 may include a memory cell array using any of the resistive memory devices illustrated in FIGS. 6 and 8 to 16 as a unit memory cell. Further, the memory cell array may use the resistive memory device or a structure in which the resistive memory device and a selection device are coupled in series, as a unit memory cell.

On the other hand, the data processing systems illustrated in FIGS. 21 and 22 may be used as a disc apparatus, a built in/external memory card of a mobile electronic apparatus, an image processor, and other application chipsets.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

1. A resistive memory device, comprising:
a first electrode layer;
a second electrode layer; and
at least one stack of a first variable resistive material layer and a second variable resistive material layer provided between the first electrode layer and the second electrode layer,
wherein the first variable resistive material layer includes a metal nitride layer, and
wherein a resistivity of the first variable resistive material layer is (i) higher than a resistivity of the first electrode layer or the second electrode layer and (ii) less than or equal to a resistivity of the second variable resistive material layer in a reset state.

2. The resistive memory device of claim 1,
wherein the first variable resistive material layer is formed over the first electrode layer and the second variable resistive material layer is formed over the first variable resistive material layer,
wherein the first variable resistive material layer has a stacked structure of a first variable resistive layer and a second variable resistive layer.

3. The resistive memory device of claim 2, wherein the first variable resistive layer includes the metal nitride layer and the second variable resistive layer includes a metal oxide layer.

4. The resistive memory device of claim 3, wherein the metal oxide layer includes any of (i) a material substantially the same as the second variable resistive material layer and having substantially the same composition ratio as the second variable resistive material layer, (ii) a material substantially the same as the second variable resistive material layer but having a composition ratio different from that of the second variable resistive material layer, and (iii) a material different from the second variable resistive material layer.

5. The resistive memory device of claim 1, wherein the first variable resistive material layer is formed over the first electrode layer and the second variable resistive material layer is formed over the first variable resistive material layer,
wherein the resistive memory device further comprises a third variable resistive material layer interposed between the second variable resistive material layer and the second electrode layer, and
wherein the third variable resistive material layer includes a metal nitride layer, and
wherein a resistivity of the third variable resistive material layer is (i) higher than the resistivity of the first electrode layer or the second electrode layer and (ii) less than or equal to the resistivity of the second variable resistive material layer in a reset state.

6. The resistive memory device of claim 5, wherein the first variable resistive material layer has a stacked structure of a first variable resistive layer and a second variable resistive layer.

7. The resistive memory device of claim 6, wherein the first variable resistive layer includes the metal nitride layer and the second variable resistive layer includes a metal oxide layer.

8. The resistive memory device of claim 7, wherein the metal oxide layer includes any of (i) a material substantially the same as the second variable resistive material layer and having substantially the same composition ratio as the second variable resistive material layer, (ii) a material substantially the same as the second variable resistive material layer but having a composition ratio different from that of the second variable resistive material layer, and (iii) a material different from the second variable resistive material layer.

9. The resistive memory device of claim 5, wherein the third variable resistive material layer has a stacked structure of a third variable resistive layer and a fourth variable resistive layer.

10. The resistive memory device of claim 9, wherein the third variable resistive layer includes the metal nitride layer and the fourth variable resistive layer includes a metal oxide layer.

11. The resistive memory device of claim 10, wherein the metal oxide layer includes any of (i) a material substantially the same as the second variable resistive material layer and having substantially the same composition ratio as the second variable resistive material layer, (ii) a material substantially the same as the second variable resistive material layer but having a composition ratio different from that of the second variable resistive material layer, and (iii) a material different from the second variable resistive material layer.

12. The resistive memory device of claim 9, wherein the first variable resistive material layer includes a first variable resistive layer and a second variable resistive layer.

13. The resistive memory device of claim 12, wherein the first variable resistive layer includes the metal nitride layer and the second variable resistive layer includes a metal oxide layer.

14. The resistive memory device of claim 13, wherein the metal oxide layer for the second variable resistive material layer includes any of (i) a material substantially the same as the second variable resistive material layer and having substantially the same composition ratio as the second variable resistive material layer, (ii) a material substantially the same as the second variable resistive material layer but having a composition ratio different from that of the second variable resistive material layer, and (iii) a material different from the second variable resistive material layer.

15. The resistive memory device of claim 1, wherein the second variable resistive material layer is formed over the first electrode layer and the first variable resistive material layer is formed over the second variable resistive material layer, and
wherein the first variable resistive material layer has a stacked structure of a first variable resistive layer and a second variable resistive layer.

16. The resistive memory device of claim 15, wherein the first variable resistive layer includes the metal nitride layer and the second variable resistive layer includes a metal oxide layer.

17. The resistive memory device of claim 16, wherein the metal oxide layer includes any of (i) a material substantially the same as the second variable resistive material layer and having substantially the same composition ratio as the second variable resistive material layer, (ii) a material substantially the same as the second variable resistive material layer but having a composition ratio different from that of the second variable resistive material layer, and (iii) a material different from the second variable resistive material layer.

18. The resistive memory device of claim 1, wherein the metal nitride layer includes a material selected from the group consisting of titanium nitride (TiN), titanium carbon nitride (TiCN), titanium aluminum nitride (TiAlN), titanium silicon nitride (TiSiN), tantalum nitride (TaN), tantalum carbon nitride (TaCN), tantalum silicon nitride (TaSiN), tantalum titanium nitride (TaTiN), titanium silicon nitride (TiSiN), hafnium nitride (HfN), zirconium nitride (ZrN), tungsten nitride (WN), aluminum nitride (AIN), and a combination thereof.

19. The resistive memory device of claim 1, wherein the metal nitride layer is formed using a source gas selected from the group consisting of nitrogen gas (N₂), hydrogen gas (H₂), ammonia gas (NH₃), argon gas (Ar), and a combination thereof.

20. The resistive memory device of claim 1 wherein the metal nitride layer has a resistivity that is greater than 150μΩ at 20 Celsius degrees and less than or equal to 10⁷μΩ at 20 Celsius degrees.

21. The resistive memory device of claim 1, wherein each of the first electrode layer and the second electrode layer includes a metal material selected from the group consisting of titanium (Ti), tantalum (Ta), tungsten (W), copper (Cu), ruthenium (Ru), platinum (Pt), nickel (Ni), iridium (Ir), aluminum (Al), zirconium (Zr), hafnium (Hf), silver (Ag), and gold (Au), a nitride layer including the metal material, a silicide layer of the metal material, and an oxide layer including the metal material.

22. The resistive memory device of claim 1, wherein the second variable resistive material layer includes any of metal oxide, a composite of a plurality of metal oxides, Perovskite, a solid-state electrolyte, and a combination thereof.

23. The resistive memory device of claim 22, wherein the second variable resistive material layer includes a material selected from the group consisting of zirconium oxide (ZrOx), nickel oxide (NiOx), hafnium oxide (HfOx), titanium oxide (TiOx), tantalum oxide (TaOx), aluminum oxide (AlOx), lanthanum oxide (LaOx), niobium oxide (NbOx), strontium titanium oxide (SrTiOx), magnesium oxide (MgOx), and a combination thereof.

24. A resistive memory apparatus, comprising:
a memory cell array including a plurality of memory cells coupled between word lines and bit lines; and
a controller configured to control a data write operation and data read operation for a selected memory cell in the memory cell array,
wherein each of the plurality of memory cells includes a resistive memory device, and
wherein the resistive memory device includes:
a first electrode layer;
a second electrode layer; and
at least one stack of a first variable resistive material layer and a second variable resistive material layer provided between the first electrode layer and the second electrode layer, and
wherein the first variable resistive material layer includes a metal nitride layer, and
wherein a resistivity of the first variable resistive material layer is (i) higher than a resistivity of the first electrode layer or the second electrode layer and (ii) less than or equal to a resistivity of the second variable resistive material layer in a reset state.

25. The resistive memory apparatus of claim 24, wherein the first variable resistive material layer further includes a metal oxide layer.

26. The resistive memory apparatus of claim 25,
wherein the first variable resistive material layer is formed over the second variable resistive material layer,
wherein the resistive memory device further includes a third variable resistive material layer stacked over a second surface of the first electrode layer,
wherein the third variable resistive material layer includes a metal nitride layer, and
wherein a resistivity of the third variable resistive material layer is (i) higher than a resistivity of the first electrode layer or the second electrode layer and (ii) less than or equal to a resistivity of the second variable resistive material layer in a reset state.

27. The resistive memory apparatus of claim 26, wherein the third variable resistive material layer further includes a metal oxide layer formed over or below of the metal nitride layer.

28. The resistive memory apparatus of claim 24, wherein the metal nitride layer includes a material selected from the group consisting of titanium nitride (TiN), titanium carbon nitride (TiCN), titanium aluminum nitride (TiAlN), titanium silicon nitride (TiSiN), tantalum nitride (TaN), tantalum carbon nitride (TaCN), tantalum silicon nitride (TaSiN), tantalum titanium nitride (TaTiN), titanium silicon nitride (TiSiN), hafnium nitride (HfN), zirconium nitride (ZrN), tungsten nitride (WN), aluminum nitride (AIN), and a combination thereof.

29. The resistive memory apparatus of claim 28,
wherein the metal nitride layer is formed using a source gas selected from the group consisting of nitrogen gas (N₂), hydrogen gas (H₂), ammonia gas (NH₃), argon gas (Ar), and a combination thereof.

30. The resistive memory apparatus of claim 24, wherein the metal nitride layer has a resistivity of greater than 150μΩ measured at 20 Celsius degrees and less than or equal to 10⁷μΩ at 20 Celsius degrees.

31. The resistive memory apparatus of claim 24, wherein the memory cell array further includes a selection device coupled to any of the first electrode layer and the second electrode layer.

32. The resistive memory apparatus of claim 24, wherein resistive memory devices are symmetrically formed with respect to a bit line.

33. The resistive memory apparatus of claim 32, wherein resistive memory devices share a common electrode layer coupled to the bit line.

34-48. (canceled)

49. The resistive memory device claim 1, wherein the memory device further includes a selection device coupled to any of the first electrode layer and the second electrode layer.

50. A resistive memory device, comprising:
a first electrode layer;
a second electrode layer; and
at least one stack of a first variable resistive material layer and a second variable resistive material layer provided between the first electrode layer and the second electrode layer,
wherein the first variable resistive material layer includes a metal nitride layer, and
wherein a resistivity of the first variable resistive material layer has a resistivity in a reset state (i) higher than that of the first electrode layer or the second electrode layer and (ii) less than or equal to 10⁷μΩ at 20 Celsius degrees.
